(19) United States
(12) Patent Application Publication
(10) Pub. No.: US 2003/0232273 A1
(43) Pub. Date: Dec. 18, 2003

(54) Acetal/alicyclic polymers and photoresist compositions

(75) Inventors: Timothy G. Adams, Sudbury, MA (US); Suzanne Coley, Mansfield, MA (US)

Correspondence Address: EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 10/268,063

(22) Filed: Oct. 9, 2002

Related U.S. Application Data
(60) Provisional application No. 60/327,800, filed on Oct. 9, 2001.

(51) Int. Cl. G03F 7/038; G03C 1/492; G03C 1/76

(52) U.S. Cl. 430/270.1; 430/326

(57) ABSTRACT

The invention includes polymers that contain an alicyclic group (cage group) and acetal group which can undergo a deblocking reaction in the presence of photogenerated acid. The invention also provides photoresists that contain such polymers, particularly for imaging at short wavelengths such as sub-300 nm and sub-200 nm.

The present application claims the benefit of U.S. provisional application No. 60/327,800, filed Oct. 9, 2001, which is incorporated herein by reference in its entirety.

### BACKGROUND OF THE INVENTION

1. Field of the Invention

The present invention relates to new polymers that contain both photoacid-labile acetal groups and alicyclic moieties such as adamantyl, norbornyl, fenchyl and the like, and the use of such polymers as a resin component for photoresist compositions, particularly chemically-amplified positive-acting resists that can be effectively imaged at short wavelengths such as sub-300 nm and sub-200 nm, particularly 248 nm and 193 nm.

2. Background

Photoresists are photosensitive films used for transfer of images to a substrate. A coating layer of a photoresist is formed on a substrate and the photoresist layer is then exposed through a photomask to a source of activating radiation. The photomask has areas that are opaque to activating radiation and other areas that are transparent to activating radiation. Exposure to activating radiation provides a photoinduced chemical transformation of the photoresist coating to thereby transfer the pattern of the photomask to the photoresist-coated substrate. Following exposure, the photoresist is developed to provide a relief image that permits selective processing of a substrate.

A photoresist can be either positive-acting or negative-acting. For most negative-acting photoresists, those coating layer portions that are exposed to activating radiation polymerize or crosslink in a reaction between a photoactive compound and polymerizable reagents of the photoresist composition. Consequently, the exposed coating portions are rendered less soluble in a developer solution than unexposed portions. For a positive-acting photoresist, exposed portions are rendered more soluble in a developer solution while areas not exposed remain comparatively less developer soluble. Photoresist compositions are described in Deforest, Photoresist Materials and Processes, McGraw Hill Book Company, New York, ch. 2, 1975 and by Moreau, Semiconductor Lithography, Principles, Practices and Materials, Plenum Press, New York, ch. 2 and 4.

More recently, chemically-amplified-type resists have been increasingly employed, particularly for formation of sub-micron images and other high performance applications. Such photoresists may be negative-acting or positive-acting and generally include many crosslinking events (in the case of a negative-acting resist) or deprotection reactions (in the case of a positive-acting resist) per unit of photogenerated acid. In the case of positive chemically-amplified resists, certain cationic photoinitiators have been used to induce cleavage of certain “blocking” groups pendant from a photoresist binder, or cleavage of certain groups that comprise a photoresist binder backbone. See, for example, U.S. Pat. Nos. 5,075,199; 4,968,581; 4,883,740; 4,810,613; and 4,491,628, and Canadian Patent Application 2,001,384. Upon cleavage of the blocking group through exposure of a coating layer of such a resist, a polar functional group is formed, e.g., carboxyl or imide, which results in different solubility characteristics in exposed and unexposed areas of the resist coating layer. See also R. D. Allen et al., Proceedings of SPIE, 2724:334-343 (1996); and P. Trefonas et al. Proceedings of the 11th International Conference on Photopolymers (Soc. Of Plastics Engineers), pp 44-58 (Oct. 6, 1997).

While currently available photoresists are suitable for many applications, current resists also can exhibit significant shortcomings, particularly in high performance applications such as formation of highly resolved sub-half micron and sub-quarter micron features.

Consequently, interest has increased in photoresists that can be photoimaged with short wavelength radiation, including exposure radiation of about 250 nm or less, or even about 200 nm or less, such as wavelengths of about 248 nm (provided by KrF laser) or 193 nm (provided by an ArF exposure tool). See European Published Application EP915382A2. Use of such short exposure wavelengths can enable formation of smaller features. Accordingly, a photoresist that yields well-resolved images upon 248 nm or 193 nm exposure could enable formation of extremely small (e.g. sub-0.25 μm) features that respond to constant industry demands for smaller dimension circuit patterns, e.g. to provide greater circuit density and enhanced device performance.

However, many current photoresists are generally designed for imaging at relatively higher wavelengths, such as G-line (436 nm) and I-line (365 nm) are generally unsuitable for imaging at short wavelengths such as sub-200 nm. Even shorter wavelength resists, such as those effective at 248 nm exposures, also are generally unsuitable for sub-200 nm exposures, such as 193 nm imaging. For instance, current photoresists can be highly opaque to extremely short exposure wavelengths such as 193 nm, thereby resulting in poorly resolved images.

### SUMMARY OF THE INVENTION

We have now found novel polymers and photoresist compositions that comprise the polymers as a resin component. Polymers of the invention contain alicyclic groups (cage groups) and acetal groups which can undergo a deblocking reaction in the presence of photogenerated acid. Preferably, an alicyclic group is integral to an acetal group, i.e. an acetal group has an alicyclic substituent.

We have found that use of such polymers of the invention can impart significant lithographic properties to photoresists containing the polymer. For instance, the alicyclic groups can provide increased contrast relative to a comparable polymer that does not contain alicyclic moieties. Additionally, the relatively bulky and higher molecular weight alicyclic groups are less prone to undesirable outgassing during a deblocking reaction. Still further, the alicyclic groups can exhibit outstanding resistance to plasma etchants used during photoresist processing. Photoacid deblocking by-products also can function as dissolution accelerators, i.e. facilitate dissolution of exposed resist regions in aqueous alkaline solution.

Alicyclic groups of polymers of the invention may be suitably carbon alicyclic groups (i.e. the group has all carbon ring members), or heteroalicylic groups (i.e. the alicyclic has one or more hetero ring members such as N, 0 or S, more typically 0 or S). Carbon alicyclic groups are preferred for at least some applications.

Such alicyclic groups are preferably a substituent of acetal groups of the polymer. For example, polymers of the invention suitably comprise groups of the formula: —O—(CXY)—O—(CX′Y′)ₙ-Alicyclic, wherein X, Y, X′, Y′ are each independent a hydrogen or non-hydrogen substituent, or one or more (CX′Y′) is an aromatic group such as phenyl, n is an integer of one or greater, and typically is 1 to about 6, 7, or 8, and Alicyclic is a carbon alicyclic or heteroalicyclic group such as optionally substituted adamantyl, optionally substituted norbornyl, and optionally substituted fenchyl. Particularly preferred carbon alicyclic groups include methyladamantyl, ethyl fencyl, optionally substituted pinanyl, optionally substituted tricyclo decanyl, particularly an alkyl-substituted tricyclo decanyl such as 8-ethyl-8-tricyclodecanyl. Exemplary heteroalicyclic groups include e.g. tetrahydrofuranyl, morpholino, and the like.

Such acetal groups may be grafted onto a preformed polymer, or may be a substituent of a monomer that can be polymerized to provide a polymer of the invention. For example, such acetal groups can be grafted onto reactive polymer groups such as hydroxy, carboxy and the like, e.g. a vinyl ether grafted onto phenolic oxygens of a phenol-containing polymer. Acrylate monomers that contain such acetal are suitably polymerized to provide a polymer of the invention.

Polymers of the invention also may contain units in addition to the above groups. For example, polymers of the invention also may contain nitrile units such as provided by polymerization of methacrylonitrile and acrylonitrile. Additional contrast enhancing groups also may be present in polymers of the invention, such as groups provided by polymerization of methacrylic acid, acrylic acid, and such acids protected as photoacid labile esters, e.g. as provided by reaction of ethoxyethyl methacrylate, t-butoxy methacrylate, t-butylmethacrylate and the like.

Generally preferred polymers of the invention contain 2, 3, 4 or 5 distinct repeat units, i.e. preferred are copolymers, terpolymers, tetrapolymers and pentapolymers that contain one or more alicyclic and acetal groups as disclosed herein.

Polymers of the invention that are employed in photoresists imaged at 193 nm preferably will be substantially free of any phenyl or other aromatic groups. For example, preferred polymers contain less than about 5 mole percent aromatic groups, more preferably less than about 1 or 2 mole percent aromatic groups, more preferably less than about 0.1, 0.02, 0.04 and 0.08 mole percent aromatic groups and still more preferably less than about 0.01 mole percent aromatic groups. Particularly preferred polymers are completely free of aromatic groups. Aromatic groups can be highly absorbing of sub-200 nm radiation and thus are undesirable for polymers used in photoresists imaged with such short wavelength radiation.

The invention also provides methods for forming relief images, including methods for forming a highly resolved relief image such as a pattern of lines where each line has essentially vertical sidewalls and a line width of about 0.40 microns or less, and even a width of about 0.25, 0.20 or 0.16 microns or less. The invention further provides articles of manufacture comprising substrates such as a microelectronic wafer substrate or liquid crystal display or other flat panel display substrate having coated thereon a polymer, photoresist or resist relief image of the invention. Other aspects of the invention are disclosed infra.

### DETAILED DESCRIPTION OF THE INVENTION

As discussed above, polymers of the invention contain an alicyclic moiety that is preferably a substituent of a photoacid-labile acetal group.

Such groups suitably can be provided by a vinyl ether that contains an alicyclic group. The vinyl ether is suitably provided by an alicyclic alcohol. For instance, an exemplary synthesis is shown in the following Scheme 1.

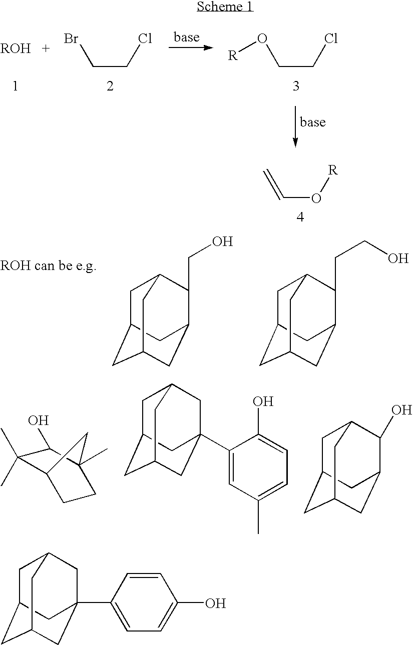

In the above Scheme 1, the alicyclic alcohol 1 is reacted with 1,2-dihaloethyl 2 in the presence of base such as a hydride, e.g. sodium hydride or lithium aluminum hydride or the like in a suitable solvent e.g. tetrahydrofuran and the like. The resulting halo-ether 3 is treated with a suitable base to provide the alicyclic vinyl ether 4. Suitable bases for the dehydrohalogenation reaction include a hydroxide such as sodium or potassium hydroxide in the presence of an alkyl ammonium salt such as tetrabutyl ammonium hydrogen sulfate. The elimination reaction can be run in a variety of solvents, including mixed solvent systems such as water and an aromatic solvent e.g. water and benzene, toluene and/or xylene.

Such vinyl ether compounds 4 then can be grafted e.g. under acidic conditions onto a preformed polymer, e.g. onto hydroxy groups of a phenolic polymer, or other reactive polymer groups such as carboxy or other hydroxy moieties. For example, the preformed polymer may be admixed in a suitable solvent together with the vinyl ether compound and an acid such as hydrocloric acid, sulfuric acid, malonic acid or a sulfuric acid. Suitable solvents include e.g. acetone, tetrahydrofuran, diglyme and dioxane.

The vinyl ether compounds 4 also may be employed as a reagent for monomers that can be polymerized to provide polymer units that contain acetal/alicyclic groups. That approach is exemplified in the following Scheme 2:

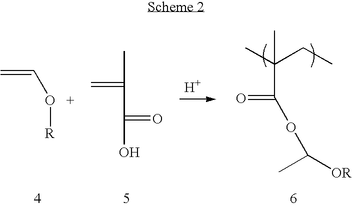

As shown in above Scheme 2, the vinyl ether 4 can be reacted in the presence of a monomer that contains a hydroxy or carboxy moiety as exemplified by methacrylic acid 5 to provide polymerized units that contain the photoacid-labile units of polymer 6 which comprise alicyclic groups R. Exemplary alicyclic R groups are depicted in the above Scheme 1 groups as R groups of ROH compounds. The units 5 may be co-polymerized with other units to provide copolymers, terpolymers, tetrapolymers and the like. For instance, suitable groups to co-polymerize with units 5 include e.g. optionally substituted styrene, optionally substituted phenol, acrylonitrile, methacrylonitrile, and the like.

The alicyclic alcohol 1 also may be employed as a reagent for monomers that can be polymerized to provide polymer units that contain acetal/alicyclic groups. That approach is exemplified in the following Scheme 3:

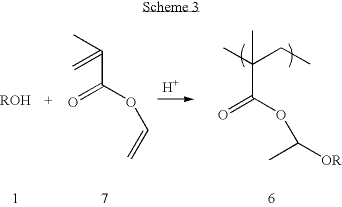

As shown in above Scheme 3, the alicyclic alcohol 1 can be reacted in the presence of a divinyl monomer that contains a hydroxy or carboxy moiety as exemplified by vinyl methacrylate 7 to provide polymerized units that contain the photoacid-labile units of polymer 6 with alicyclic groups R. Exemplary alicyclic R groups are depicted in the Scheme 1 above as compounds ROH. As discussed above with respect to units 5 of Scheme 2, units 7 may be co-polymerized with other units to provide copolymers, terpolymers, tetrapolymers and the like. For instance, suitable groups to co-polymerize with units 5 include e.g. optionally substituted styrene, optionally substituted phenol, acrylonitrile, methacrylonitrile, and the like.

Preferred alicyclic moieties of polymers of the invention have rather large volume. Such bulky alicyclic groups can provide enhanced resolution when used in photoresists of the invention.

More particularly, preferred alicyclic groups will have a molecular volume of at least about 125 or about 130 Å³, more preferably a molecular volume of at least about 135, 140, 150, 155, 160, 165, 170, 175, 180, 185, 190, 195, or 200 Å³. Alicyclic groups larger than about 220 or 250 A³ may be less preferred, in at least some applications. References herein to molecular volumes designate volumetric size as determined by standard computer modeling, which provides optimized chemical bond lengths and angles. A preferred computer program for determining molecular volume as referred to herein is Alchemy 2000, available from Tripos. For a further discussion of computer-based determination of molecular size, see T Omote et al, Polymers for Advanced Technologies, volume 4, pp. 277-287.

Particularly preferred alicyclic groups of polymers of the invention include tertiary groups such as the following, where the wavy line depicts a bond to the carboxyl oxygen of the ester group, and R is suitably hydrogen or more preferably optionally substituted alkyl, particularly C₁₋₈ alkyl such as methyl, ethyl, etc.

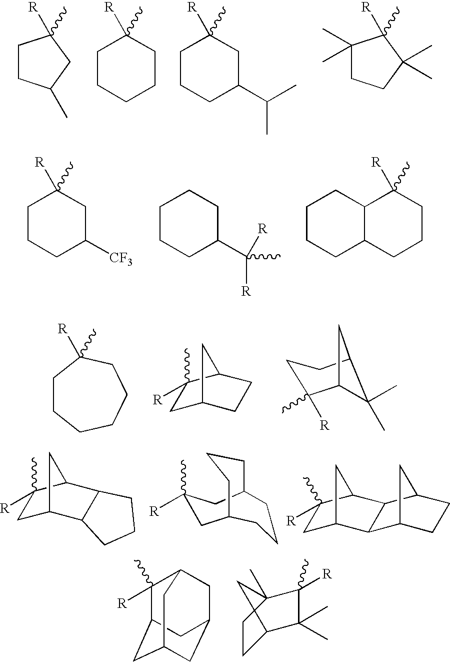

Polymers of the invention also may contain photoacid-labile groups that do not contain an alicyclic moiety, including photoacid labile groups other than acetal groups. For example, polymers of the invention may contain photoacid-labile ester units, such as a photoacid-labile alkyl ester. Generally, the carboxyl oxygen (i.e. the carboxyl oxygen as underlined as follows: —C(═O)O) of the photoacid-labile ester will be covalently linked to the quaternary carbon. Branched photoacid-labile esters are generally preferred such as t-butyl and —C(CH₃)₂CH(CH₃)₂.

Also preferred photoacid-labile groups in addition to acetal groups of polymers of the invention are esters that contain a tertiary alicyclic hydrocarbon ester moiety. Preferred tertiary alicyclic hydrocarbon ester moieties are polycyclic groups such adamantyl, ethylfencyl or a tricyclo decanyl moiety. References herein to a “tertiary alicyclic ester group” or other similar term indicate that a tertiary alicyclic ring carbon is covalently linked to the ester oxygen, i.e. —C(═O)O—TR′ where T is a tertiary ring carbon of alicyclic group R′, including those groups depicted above.

As discussed above, polymers of the invention also may contain additional units such as cyano units, lactone units or anhydride units. For example, acrylonitrile or methacrylonitrile may be polymerized to provide pendant cyano groups, or maleic anhydride may be polymerized to provide a fused anhydride unit.

As discussed above, polymers of the invention are preferably employed in photoresists imaged at short wavelengths, particularly sub-300 nm such as 248 nm and sub-200 nm such as 193 nm and 157 nm. For such higher wavelength applications, such as above 200 nm, including 248 nm, the polymer may suitably contain aromatic units, e.g. polymerized styrene or hydroxystyrene units.

As discussed, various moieties of polymers of the invention may be optionally substituted. A “substituted” substituent may be substituted at one or more available positions, typically 1, 2, or 3 positions by one or more suitable groups such as e.g. halogen (particularly F, Cl or Br); cyano; C₁₋₈ alkyl; C₁₋₈ alkoxy; C₁₋₈ alkylthio; C₁₋₈ alkylsulfonyl; C₂₋₈ alkenyl; C₂₋₈ alkynyl; hydroxyl; nitro; alkanoyl such as a C₁₋₆ alkanoyl e.g. acyl and the like; etc.

Polymers of the invention can be prepared by a variety of methods. One suitable method is an addition reaction which may include free radical polymerization, e.g., by reaction of selected monomers to provide the various units as discussed above in the presence of a radical initiator under an inert atmosphere (e.g., N₂ or argon) and at elevated temperatures such as about 70° C. or greater, although reaction temperatures may vary depending on the reactivity of the particular reagents employed and the boiling point of the reaction solvent (if a solvent is employed). Suitable reaction solvents include e.g. tetrahydrofuran, ethyl lactate and the like. Suitable reaction temperatures for any particular system can be readily determined empirically by those skilled in the art based on the present disclosure. A variety of free radical initiators may be employed. For example, azo compounds may be employed such as azo-bis-2,4-dimethylpentanenitrile. Peroxides, peresters, peracids and persulfates also could be employed.

Other monomers that can be reacted to provide a polymer of the invention can be identified by those skilled in the art. For example, maleic anhydride is a preferred reagent to provide fused anhydride polymer units. Itaconic anhydride also is a preferred reagent to provide anhydride polymer units, preferably where the itaconic anhydride has purified such as by extraction with chloroform prior to polymerization. Vinyl lactones are also preferred reagents, such as alpha-butyrolactone. Phenolic and other phenyl units can be provided by polymerization of vinyl phenyl, and other substituted and unsubstituted phenyl groups such as styrene.

Preferably a polymer of the invention will have a weight average molecular weight (Mw) of about 800 or 1,000 to about 100,000, more preferably about 2,000 to about 30,000, still more preferably from about 2,000 to 15,000 or 20,000, with a molecular weight distribution (Mw/Mn) of about 3 or less, more preferably a molecular weight distribution of about 2 or less. Molecular weights (either Mw or Mn) of the polymers of the invention are suitably determined by gel permeation chromatography.

Polymers of the invention used in photoresist formulations should contain a sufficient amount of photoacid labile groups to enable formation of resist relief images as desired. For instance, suitable amount of acid labile groups will be at least 1 mole percent of total units of the polymer, more preferably about 2 to 50 mole percent, still more typically about 3 to 30 or 40 mole percent of total polymer units. See the examples which follow for exemplary preferred polymers.

As discussed above, the polymers of the invention are highly useful as a resin component in photoresist compositions, particularly chemically-amplified positive resists. Photoresists of the invention in general comprise a photoactive component and a resin component that comprises a polymer as described above.

The resin binder component should be used in an amount sufficient to render a coating layer of the resist developable with an aqueous alkaline developer.

The resist compositions of the invention also comprise a photoacid generator (i.e. “PAG”) that is suitably employed in an amount sufficient to generate a latent image in a coating layer of the resist upon exposure to activating radiation. Preferred PAGs for imaging at 193 nm and 248 nm imaging include imidosulfonates such as compounds of the following formula:

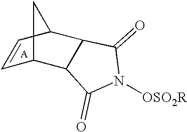

wherein R is camphor, adamantane, alkyl (e.g. C₁₋₁₂ alkyl) and perfluoroalkyl such as perfluoro(C₁₋₁₂alkyl), particularly perfluorooctanesulfonate, perfluorononanesulfonate and the like. A specifically preferred PAG is N-[(perfluorooctanesulfonyl)oxy]-5-norbornene-2,3-dicarboximide.

Sulfonate compounds are also suitable PAGs, particularly sulfonate salts. Two suitable agents for 193 nm and 248 m imaging are the following PAGS 1 and 2:

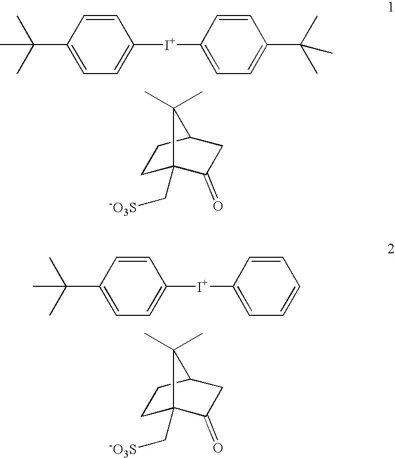

Such sulfonate compounds can be prepared as disclosed in European Patent Application 96118111.2 (publication number 0783136), which details the synthesis of above PAG 1.

Also suitable are the above two iodonium compounds complexed with anions other than the above-depicted camphorsulfonate groups. In particular, preferred anions include those of the formula RSO₃— where R is adamantane, alkyl (e.g. C₁₋₁₂ alkyl) and perfluoroalkyl such as perfluoro (C₁₋₁₂alkyl), particularly perfluorooctanesulfonate, perfluorobutanesulfonate and the like.

Other known PAGS also may be employed in the resists of the invention. Particularly for 193 nm imaging, generally preferred are PAGS that do not contain aromatic groups, such as the above-mentioned imidosulfonates, in order to provide enhanced transparency.

A preferred optional additive of resists of the invention is an added base, particularly tetrabutylammonium hydroxide (TBAH), or tetrabutylammonium lactate, which can enhance resolution of a developed resist relief image. For resists imaged at 193 nm, a preferred added base is a hindered amine such as diazabicyclo undecene or diazabicyclononene. The added base is suitably used in relatively small amounts, e.g. about 0.03 to 5 percent by weight relative to the total solids.

Photoresists of the invention also may contain other optional materials. For example, other optional additives include anti-striation agents, plasticizers, speed enhancers, etc. Such optional additives typically will be present in minor concentrations in a photoresist composition except for fillers and dyes which may be present in relatively large concentrations, e.g., in amounts of from about 5 to 30 percent by weight of the total weight of a resist's dry components.

The resists of the invention can be readily prepared by those skilled in the art. For example, a photoresist composition of the invention can be prepared by dissolving the components of the photoresist in a suitable solvent such as, for example, ethyl lactate, ethylene glycol monomethyl ether, ethylene glycol monomethyl ether acetate, propylene glycol monomethyl ether; propylene glycol monomethyl ether acetate and 3-ethoxyethyl propionate. Typically, the solids content of the composition varies between about 5 and 35 percent by weight of the total weight of the photoresist composition. The resin binder and photoactive components should be present in amounts sufficient to provide a film coating layer and formation of good quality latent and relief images. See the examples which follow for exemplary preferred amounts of resist components.

The compositions of the invention are used in accordance with generally known procedures. The liquid coating compositions of the invention are applied to a substrate such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning.

The resist compositions of the invention are suitably applied to substrates conventionally used in processes involving coating with photoresists. For example, the composition may be applied over silicon wafers or silicon wafers coated with silicon dioxide for the production of microprocessors and other integrated circuit components. Aluminum-aluminum oxide, gallium arsenide, ceramic, quartz, copper, glass substrates and the like are also suitably employed.

Following coating of the photoresist onto a surface, it is dried by heating to remove the solvent until preferably the photoresist coating is tack free. Thereafter, it is imaged through a mask in conventional manner. The exposure is sufficient to effectively activate the photoactive component of the photoresist system to produce a patterned image in the resist coating layer and, more specifically, the exposure energy typically ranges from about 1 to 100 mJ/cm², dependent upon the exposure tool and the components of the photoresist composition.

As discussed above, coating layers of the resist compositions of the invention are preferably photoactivated by a short exposure wavelength, particularly a sub-300 and sub-200 nm exposure wavelength. As discussed above, 248 nm and 193 nm are particularly preferred exposure wavelengths. 157 nm also is a preferred exposure wavelength. However, the resist compositions of the invention also may be suitably imaged at higher wavelengths. For example, a resin of the invention can be formulated with an appropriate PAG and sensitizer if needed and imaged at higher wavelengths e.g. 365 nm.

Following exposure, the film layer of the composition is preferably baked at temperatures ranging from about 70° C. to about 160° C. Thereafter, the film is developed. The exposed resist film is rendered positive working by employing a polar developer, preferably an aqueous based developer such as quaternary ammonium hydroxide solutions such as a tetra-alkyl ammonium hydroxide solution; various amine solutions preferably a 0.26 N tetramethylammonium hydroxide, such as ethyl amine, n-propyl amine, diethyl amine, di-n-propyl amine, triethyl amine, or methyldiethyl amine; alcohol amines such as diethanol amine or triethanol amine; cyclic amines such as pyrrole, pyridine, etc. In general, development is in accordance with procedures recognized in the art.

Following development of the photoresist coating over the substrate, the developed substrate may be selectively processed on those areas bared of resist, for example by chemically etching or plating substrate areas bared of resist in accordance with procedures known in the art. For the manufacture of microelectronic substrates, e.g., the manufacture of silicon dioxide wafers, suitable etchants include a gas etchant, e.g. a halogen plasma etchant such as a chlorine or fluorine-based etchant such a Cl₂ or CF₄/CHF₃ etchant applied as a plasma stream. After such processing, resist may be removed from the processed substrate using known stripping procedures.

All documents mentioned herein are incorporated herein by reference. the following non-limiting example is illustrative of the invention.

### EXAMPLE 1

A photoresist composition is prepared by admixing the following components where amounts are expressed as weight percent of solids (all components except solvent) and the resist is formulated as a 90 percent fluid formulation:

| Component | Amount |
|---|---|
| Resin | balance solids |
| PAG | 4 |
| Basic additive | 0.5 |
| Surfactant | 0.2 |
| Solvent | to 10 weight percent solids |

In the resist, the resin has the following structure which can be prepared as set forth in the above Schemes.

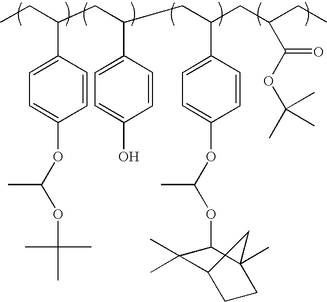

In the resist, the PAG is di-t-butylphenyliodonium camphorsulfonate (PAG 2 above);-the basic additive is tetrabutylammonium hydroxide; the surfactant is Silwet 7604; and the solvent is ethyl lactate.

The formulated resist composition is spin coated onto HMDS vapor primed 4 inch silicon wafers and softbaked via a vacuum hotplate at 90° C. for 60 seconds. The resist coating layer is exposed through a photomask at 248 nm, and then the exposed resist coating layer is post-exposure baked at 110° C. The coated wafers are then treated with 0.26 N aqueous tetramethylammonium hydroxide solution to develop the imaged resist layer.

The foregoing description of the invention is merely illustrative thereof, and it is understood that variations and modification can be made without departing from the spirit or scope of the invention as set forth in the following claims.

What is claimed is:

1. A photoresist composition comprising a photoactive component and a polymer that comprises an alicyclic unit and a photoacid-labile acetal unit.

2. The photoresist of claim 1 wherein the alicyclic unit is a substituent of the acetal unit.

3. The photoresist of claims 1 or 2 wherein the alicylic unit is a carbon alicyclic unit.

4. The photoresist of claims 1 or 2 wherein the alicyclic unit is a hetero alicylic unit.

5. The photoresist of claim 1 wherein the acetal unit is a polymer unit separate from the alicyclic unit.

6. The photoresist of any one of claims 1 through 4 wherein the polymer comprises a polymerized acrylate that comprises an acetal group and an alicyclic group.

7. The photoresist of any one of claims 1 through 6 wherein the polymer comprises phenyl groups with one or more acetal ring substituents.

8. The photoresist of any one of claims 1 through 7 wherein the polymer comprises aromatic units.

9. The photoresist of any one of claims 1 through 8 wherein the polymer comprises phenyl units.

10. The photoresist of any one of claims 1 through 6 wherein the polymer is substantially free of aromatic units.

11. The photoresist of any one of claims 1 through 10 wherein the polymer further comprises lactone, anhydride, or nitrile units.

12. The photoresist of any one of claims 1 through 11 wherein the polymer is a terpolymer, tetrapolymer or a pentapolymer.

13. A method of forming a positive photoresist relief image, comprising:
(a) applying a coating layer of a photoresist of any one of claims 1 through 12 on a substrate; and
(b) exposing and developing the photoresist layer to yield a relief image.

14. The method of claim 13 wherein the photoresist layer is exposed with radiation having a wavelength of less than about 300 nm.

15. The method of claim 13 wherein the photoresist layer is exposed with radiation having a wavelength of less than about 200 nm.

16. The method of claim 13 wherein the photoresist layer is exposed with radiation having a wavelength of about 248 nm, 193 nm or 157 mm.

17. An article of manufacture comprising a microelectronic wafer substrate having coated thereon a layer of the photoresist composition of any one of claims 1 through 12.

18. A polymer that comprises an alicyclic unit and a photoacid-labile acetal unit.

19. A polymer of claim 18 wherein the alicyclic unit is a substituent of the acetal unit.

20. The polymer of claim 18 wherein the acetal unit is a polymer unit separate from the alicyclic unit.

21. The polymer of claims 18, 19 or 20 wherein the alicylic unit is a carbon alicyclic unit.

22. The polymer of claims 18, 19 or 20 wherein the alicyclic unit is a hetero alicylic unit.

23. The polymer of any one of claims 18 through 22 wherein the polymer comprises a polymerized acrylate that comprises an acetal group and an alicyclic group.

24. The polymer of any one of claims 18 through 23 wherein the polymer comprises phenyl groups with one or more acetal ring substituents.

25. The polymer of any one of claims 18 through 24 wherein the polymer comprises aromatic units.

26. The polymer of any one of claims 18 through 24 wherein the polymer comprises phenyl units.

27. The polymer of any one of claims 18 through 24 wherein the polymer is substantially free of aromatic units.

28. The polymer of any one of claims 18 through 27 wherein the polymer further comprises lactone, anhydride, or nitrile units.

29. The polymer of any one of claims 18 through 28 wherein the polymer is a terpolymer, tetrapolymer or a pentapolymer.
